(19) United States
(12) Patent Application Publication
(10) Pub. No.: US 2017/0231116 A1
(43) Pub. Date: Aug. 10, 2017

(54) HEAT DISSIPATING DEVICE

(71) Applicant: AURAS Technology Co., Ltd., New Taipei City (TW)

(72) Inventors: AN-CHIH WU, New Taipei City (TW); CHE-CHIA CHANG, New Taipei City (TW); YI-WUN CHEN, New Taipei City (TW)

(21) Appl. No.: 15/212,762

(22) Filed: Jul. 18, 2016

Related U.S. Application Data
(60) Provisional application No. 62/291,798, filed on Feb. 5, 2016.

(30) Foreign Application Priority Data
Jun. 24, 2016 (TW) 105119949

(51) Int. Cl. H05K 7/20

(52) U.S. Cl. CPC H05K 7/20336

(57) ABSTRACT

A heat dissipating device and a method for increasing heat conduction of the heat dissipating device are provided. The heat dissipating device at least includes a fin group, a heat conduction block with a coupling region and plural heat pipes. Firstly, the heat conduction block is placed in the fin group. Then, first-part pipe bodies of at least portions of the plural heat pipes are placed in the coupling region. The exposed surfaces of the first-part pipe bodies are partially protruded over an outer edge surface of the heat conduction block. Then, in response to an external force, the exposed surfaces of the first-part pipe bodies are located beside and coplanar or nearly coplanar with the outer edge surface of the heat conduction block. The contact area of the first-part pipe bodies in the coupling region is increased, and thus the heat dissipating efficiency is enhanced.

### CROSS-REFERENCE TO RELATED APPLICATION

This application claims priority to U.S. Provisional Patent Application No. 62/291,798 entitled “HEAT DISSIPATING DEVICE” filed Feb. 5, 2016, the contents of which are incorporated herein by reference.

### FIELD OF THE INVENTION

The present invention relates to a heat dissipating device, and more particularly to a heat dissipating device with enhanced heat conduction performance.

### BACKGROUND OF THE INVENTION

With increasing development of the modern electronic industry, the sizes of various package chips applied to electronic products are gradually decreased. However, as the performance of the electronic device increases, the circuitry configuration inside the integrated circuit becomes more and more complicated. Consequently, during operation of the electronic product, a great amount of heat is generated. If the heat cannot be dissipated away quickly, the inner integrated circuit of the package chip is possibly burnt out. For solving this problem, various heat dissipating structures or heat dissipating devices applied to electronic products are developed vigorously.

For example, a conventional heat sink usually comprises a heat conduction base, plural fins and an external cooling fan. The heat conduction base is made of a metallic material such as copper or aluminum. The fins are integrally formed. The heat generated by the package chip can be quickly dissipated away through the heat sink. With increasing development of the electronic industry, the conventional heat sink is not satisfied. Instead, the heat sink with good heat dissipating performance is adopted. The heat sink with good heat dissipating performance not only has increased heat transfer area but also has a heat conduction mechanism (such as a water cool mechanism or a heat pipe mechanism). Since the space is effectively utilized, the stability of using the electronic product is enhanced. In the heat sink with heat pipes, plural insertion slots corresponding to the heat pipes are formed in the heat conduction base. Generally, first portions of the heat pipes are embedded within the insertion slots, and second portions of the heat pipes are disposed in a fin group. Since a working liquid circulates in the heat pipe through thermal evaporation and cooling condensation, the heat can be quickly removed from the heat conduction base. However, since the cross sections of these heat pipes are circular, the heat pipes cannot be effectively contacted with the heat source to transfer heat.

For allowing the heat sink to be in direct contact with the heat source more effectively, the circular heat pipes are disposed within insertion slots in the bottom surface of the heat conduction base. After the circular heat pipes are disposed within the insertion slots, the circular heat pipes are machined a non-circular heat pipes with rounded corners (e.g., flat heat pipes or semi-circular heat pipes) by a stamping process or a roll pressing process. Consequently, the heat source can be directly contacted with the heat pipes. However, since the fractions of the heat pipes for removing heat from the conventional non-circular heat pipes (i.e., the contact portions between the heat source and the heat pipes) are very limited, the heat dissipating efficiency of the heat dissipating device is not high enough.

As mentioned above, with increasing development of the modern electronic industry, the specification size of the heat source (e.g., the package chip) is gradually reduced or the size reduction of the package chip is usually necessary. Therefore, it is an important issue for efficiently increasing the heat dissipating performance of the heat pipes to remove heat from the heat source, effectively utilizing the contact areas between the heat pipes and the heat source and effectively increasing the contact areas between heat pipes.

### SUMMARY OF THE INVENTION

For solving the drawbacks of the conventional technologies, the present invention provides a heat dissipating device with enhanced heat conduction performance in order to enhance the heat dissipating efficiency.

In accordance with an aspect of the present invention, there is provided a heat dissipating device. The heat dissipating device at least includes a fin group, a heat conduction block and plural heat pipes. The heat conduction block has a coupling region. The heat conduction block is installed in the fin group. The coupling region has an accommodation space. First ends of at least portions of the plural heat pipes include first-part pipe bodies. The first-part pipe bodies are included in the coupling region. The first-part pipe bodies are received within the accommodation space. Moreover, an exposed region of the first-part pipe bodies is located beside and coplanar or nearly coplanar with an outer edge surface of the heat conduction block in response to an external force. Every two adjacent ones of the first-part pipe bodies are in surface contact with each other through respective flat pipe walls, so that the first-part pipe bodies are abutted against each other to transfer heat directly.

In an embodiment, every two adjacent ones of the first-part pipe bodies at least include a first flat pipe wall and a second flat pipe wall, respectively. The first flat pipe wall and the second flat pipe wall are in surface contact with each other and abutted against each other to transfer heat directly.

In an embodiment, the fin group at least includes a first fin assembly with a recess, and the heat conduction block is received in the recess.

In an embodiment, each of the first-part pipe bodies is a polygonal pipe body with plural flat pipe walls. The polygonal pipe body is a regular pipe body or an irregular pipe body.

In an embodiment, the regular pipe body is one of a triangular pipe body and a nearly-triangular pipe body, or the regular pipe body is one of a rectangular pipe body and a nearly-rectangular pipe body.

In an embodiment, the fin group further includes a second fin assembly. The second fin assembly is located beside and extended to second ends of the at least portions of the plural heat pipes, and the at least portions of the plural heat pipes are penetrated through the second fin assembly.

In an embodiment, a thermal conductivity coefficient of the first fin assembly and a thermal conductivity coefficient of the second fin assembly are both higher than a thermal conductivity coefficient of the heat conduction block.

In an embodiment, the exposed region of the first-part pipe bodies is contacted with a heat generation unit, and the heat from the heat generation unit is conducted by the first-part pipe bodies.

In an embodiment, the heat dissipating device further includes a temperature homogenizing plate, and the uniform temperature plate is arranged between the heat generation unit and the first-part pipe bodies.

In accordance with another aspect of the present invention, there is provided a heat dissipating device. The heat dissipating device at least includes a fin group, a heat conduction block and plural heat pipes. The heat conduction block has a coupling region. The heat conduction block is installed in the fin group. At least portions of the plural heat pipes include first-part pipe bodies. The first-part pipe bodies are included in the coupling region. Moreover, an exposed region of the first-part pipe bodies is located beside and coplanar or nearly coplanar with an outer edge surface of the heat conduction block. Every two adjacent ones of the first-part pipe bodies are in surface contact with each other through respective flat pipe walls, so that the first-part pipe bodies are abutted against each other to transfer heat directly.

In an embodiment, the coupling region has an accommodation space, and the first-part pipe bodies of the at least portions of the plural heat pipes are embedded in or locked in the accommodation space.

In an embodiment, every two adjacent ones of the first-part pipe bodies at least include a first flat pipe wall and a second flat pipe wall, respectively. The first flat pipe wall and the second flat pipe wall are in surface contact with each other and abutted against each other to transfer heat directly.

In an embodiment, the fin group at least includes a first fin assembly with a recess. The recess includes a first concave structure and a second concave structure beside the first concave structure. The heat conduction block is received in the first concave structure. Moreover, second-part pipe bodies of the at least portions of the plural heat pipes are received in the second concave structure.

In an embodiment, the second-part pipe bodies of the at least portions of the plural heat pipes are located beside and extended from first ends of the first-part pipe bodies.

In an embodiment, the first-part pipe bodies and the second-part pipe bodies of the at least portions of the plural heat pipes are integrally formed with each other, or the first-part pipe bodies and the second-part pipe bodies of the at least portions of the plural heat pipes are produced by a stamping process or a roll pressing process after being disposed in the coupling region.

In an embodiment, the fin group further includes a second fin assembly. The second fin assembly is located beside and extended to second ends of the at least portions of the plural heat pipes, and the at least portions of the plural heat pipes are penetrated through the second fin assembly.

In an embodiment, a thermal conductivity coefficient of the first fin assembly and a thermal conductivity coefficient of the second fin assembly are both higher than a thermal conductivity coefficient of the heat conduction block. Consequently, the heat dissipating efficiency of the first fin assembly and the heat dissipating efficiency of the second fin assembly are enhanced.

In an embodiment, each of the first-part pipe bodies is a polygonal pipe body with plural flat pipe walls. Alternatively, each of the second-part pipe bodies is a second polygonal pipe body with plural flat pipe walls.

In an embodiment, the polygonal pipe body and the second polygonal pipe body are regular pipe bodies or irregular pipe bodies.

In an embodiment, the regular pipe body is one of a triangular pipe body and a nearly-triangular pipe body, or the regular pipe body is one of a rectangular pipe body and a nearly-rectangular pipe body.

In an embodiment, the exposed region of the first-part pipe bodies is contacted with a heat generation unit, and the heat from the heat generation unit is conducted by the first-part pipe bodies.

In an embodiment, the heat dissipating device further includes a temperature homogenizing plate, and the uniform temperature plate is arranged between the heat generation unit and the first-part pipe bodies.

In an embodiment, the plural heat pipes are flat heat pipes or circular heat pipes.

In accordance with another aspect of the present invention, there is provided a heat dissipating device. The heat dissipating device at least includes a fin group, a heat conduction block and plural heat pipes. The heat conduction block has a coupling region. The heat conduction block is installed in the fin group. At least portions of the plural heat pipes include first-part pipe bodies. The first-part pipe bodies are included in the coupling region. Every two adjacent ones of the first-part pipe bodies are in surface contact with each other through respective flat pipe walls, so that the first-part pipe bodies are abutted against each other to transfer heat directly.

In an embodiment, the coupling region has an accommodation space, and the first-part pipe bodies of the at least portions of the plural heat pipes are embedded in or locked in the accommodation space.

In an embodiment, every two adjacent ones of the first-part pipe bodies at least include a first flat pipe wall and a second flat pipe wall, respectively. The first flat pipe wall and the second flat pipe wall are in surface contact with each other and abutted against each other to transfer heat directly.

In an embodiment, the fin group at least includes a first fin assembly and a second fin assembly. The first fin assembly and the second fin assembly are respectively connected to first ends and second ends of the at least portions of the plural heat pipes.

In an embodiment, the first fin assembly at least includes a recess, and the heat conduction block is received in the recess. Moreover, the at least portions of the plural heat pipes are penetrated through the second fin assembly.

In an embodiment, each of the first-part pipe bodies is a polygonal pipe body with plural flat pipe walls.

In an embodiment, the polygonal pipe body is a regular pipe body or an irregular pipe body.

In an embodiment, the regular pipe body is one of a triangular pipe body and a nearly-triangular pipe body, or the regular pipe body is one of a rectangular pipe body and a nearly-rectangular pipe body

In an embodiment, an exposed region of the first-part pipe bodies is located beside and coplanar or nearly coplanar with an outer edge surface of the heat conduction block.

In an embodiment, the first-part pipe bodies are integrally formed with each other to define the exposed region of, or the exposed region of the first-part pipe bodies is created after the first-part pipe bodies are disposed in the coupling region and subjected to a stamping process or a roll pressing process.

In an embodiment, the exposed region of the first-part pipe bodies is contacted with a heat generation unit, and the heat from the heat generation unit is conducted by the first-part pipe bodies.

In an embodiment, the heat dissipating device further includes a temperature homogenizing plate, and the uniform temperature plate is arranged between the heat generation unit and the first-part pipe bodies.

In accordance with another aspect of the present invention, there is provided a heat dissipating device. The heat dissipating device at least includes a fin group, a heat conduction block and plural heat pipes. The heat conduction block has a coupling region. The heat conduction block is installed in the fin group. First ends of at least portions of the plural heat pipes include first-part pipe bodies. The first-part pipe bodies are included in the coupling region. Moreover, an exposed region of the first-part pipe bodies is located beside and coplanar or nearly coplanar with an outer edge surface of the heat conduction block in response to an external force. Every two adjacent ones of the first-part pipe bodies are in surface contact with each other through respective flat pipe walls, so that the first-part pipe bodies are abutted against each other to transfer heat directly.

In an embodiment, the coupling region has an accommodation space, and the first-part pipe bodies of the at least portions of the plural heat pipes are embedded in or locked in the accommodation space.

In an embodiment, every two adjacent ones of the first-part pipe bodies at least include a first flat pipe wall and a second flat pipe wall, respectively. The first flat pipe wall and the second flat pipe wall are in surface contact with each other and abutted against each other to transfer heat directly.

In an embodiment, the fin group at least includes a first fin assembly with a recess, and the heat conduction block is received in the recess.

In an embodiment, each of the first-part pipe bodies is a polygonal pipe body with plural flat pipe walls.

In an embodiment, the polygonal pipe body is a regular pipe body or an irregular pipe body.

In an embodiment, the regular pipe body is one of a triangular pipe body and a nearly-triangular pipe body, or the regular pipe body is one of a rectangular pipe body and a nearly-rectangular pipe body.

In an embodiment, the fin group further includes a second fin assembly. The second fin assembly is located beside and extended to second ends of the at least portions of the plural heat pipes, and the at least portions of the plural heat pipes are penetrated through the second fin assembly.

In an embodiment, a thermal conductivity coefficient of the first fin assembly and a thermal conductivity coefficient of the second fin assembly are both higher than a thermal conductivity coefficient of the heat conduction block. Consequently, the heat dissipating efficiency of the first fin assembly and the heat dissipating efficiency of the second fin assembly are enhanced.

In an embodiment, the exposed region of the first-part pipe bodies is contacted with a heat generation unit, and the heat from the heat generation unit is conducted by the first-part pipe bodies.

In an embodiment, the heat dissipating device further includes a temperature homogenizing plate, and the uniform temperature plate is arranged between the heat generation unit and the first-part pipe bodies.

In accordance with another aspect of the present invention, there is provided a method for increasing heat conduction of a heat dissipating device. The heat dissipating device at least includes a fin group, a heat conduction block with a coupling region and plural heat pipes. The method includes the following steps. Firstly, the heat conduction block is placed in the fin group. The first-part pipe bodies of at portions of the plural heat pipes are placed in the coupling region. The first-part pipe bodies are located at first ends of the at portions of the plural heat pipes. The exposed surfaces of the first-part pipe bodies are partially protruded over an outer edge surface of the heat conduction block. Then, an external force is applied to the exposed surfaces of the first-part pipe bodies. Consequently, the exposed surfaces of the first-part pipe bodies are located beside and coplanar or nearly coplanar with the outer edge surface of the heat conduction block.

In an embodiment, the coupling region has an accommodation space, and the first-part pipe bodies of the at least portions of the plural heat pipes are received within the accommodation space.

In an embodiment, every two adjacent ones of the first-part pipe bodies at least include a first flat pipe wall and a second flat pipe wall, respectively. The first flat pipe wall and the second flat pipe wall are in surface contact with each other and abutted against each other to transfer heat directly.

In an embodiment, the fin group at least includes a first fin assembly with a recess, and the heat conduction block is received in the recess.

In an embodiment, each of the first-part pipe bodies is a polygonal pipe body with plural flat pipe walls.

In an embodiment, the polygonal pipe body is a regular pipe body or an irregular pipe body.

In an embodiment, the regular pipe body is one of a triangular pipe body and a nearly-triangular pipe body, or the regular pipe body is one of a rectangular pipe body and a nearly-rectangular pipe body.

In an embodiment, the fin group further includes a second fin assembly. The second fin assembly is located beside and extended to second ends of the at least portions of the plural heat pipes, and the at least portions of the plural heat pipes are penetrated through the second fin assembly.

In an embodiment, a thermal conductivity coefficient of the first fin assembly and a thermal conductivity coefficient of the second fin assembly are both higher than a thermal conductivity coefficient of the heat conduction block.

In an embodiment, the exposed surfaces of the first-part pipe bodies are contacted with a heat generation unit, and the heat from the heat generation unit is conducted by the first-part pipe bodies.

In an embodiment, the heat dissipating device further includes a temperature homogenizing plate, and the uniform temperature plate is arranged between the heat generation unit and the first-part pipe bodies.

From the above descriptions, the present invention provides a heat dissipating device. The heat pipes of the heat dissipating device have improved profiles. Moreover, at least two heat pipes are cooperatively used to enhance the heat dissipating performance. Particularly, the pipe bodies of the heat pipes have the structures of triangular prisms or other prisms with larger contact surfaces. Since the contact area between the adjacent heat pipes is increased, the heat dissipating performance of the heat pipes to remove heat from the heat generation unit is effectively increased.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic perspective view illustrating the basic concepts of a heat dissipating device according to a first embodiment of the present invention;

FIG. 1B is a schematic exploded view illustrating the heat dissipating device of FIG. 1A;

FIG. 2A is a schematic perspective view illustrating the heat pipes and the heat conduction block of the heat dissipating device of FIG. 1A;

FIG. 2B is a schematic perspective view illustrating the heat pipes and the heat conduction block of the heat dissipating device of FIG. 2A and taken along another viewpoint;

FIG. 2C is a schematic front view illustrating the heat pipes and the heat conduction block of the heat dissipating device of FIG. 2A;

FIG. 3A is a schematic perspective view illustrating the heat pipes of the heat dissipating device of FIG. 1A;

FIG. 3B is a schematic perspective view illustrating the heat pipes of FIG. 3A;

FIG. 4 is a schematic front view illustrating the basic concepts of a heat dissipating device according to a second embodiment of the present invention; and

FIG. 5 is a flowchart illustrating a method for increasing heat conduction of a heat dissipating device according to an embodiment of the present invention.

### DETAILED DESCRIPTION OF THE PREFERRED EMBODIMENT

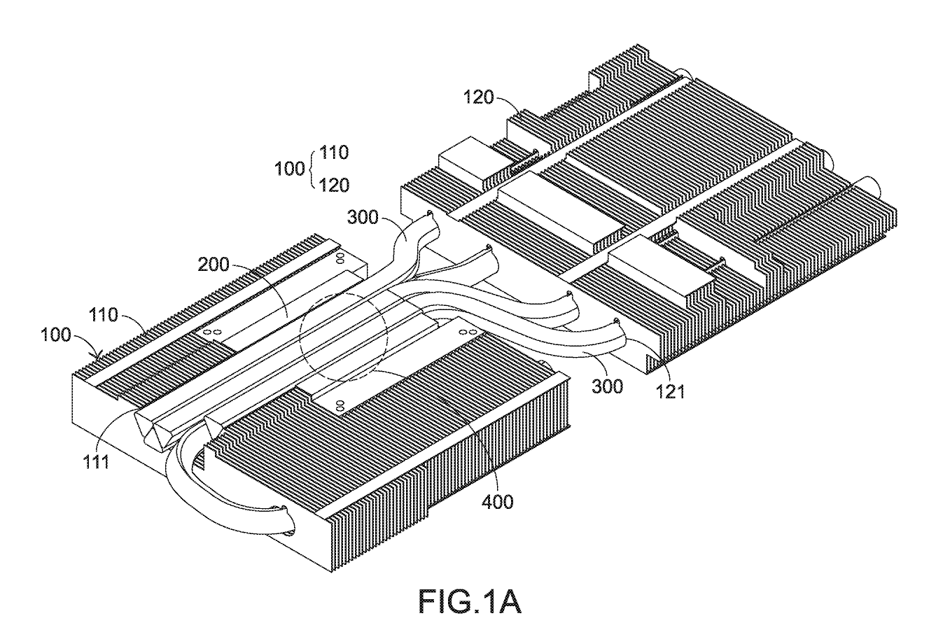

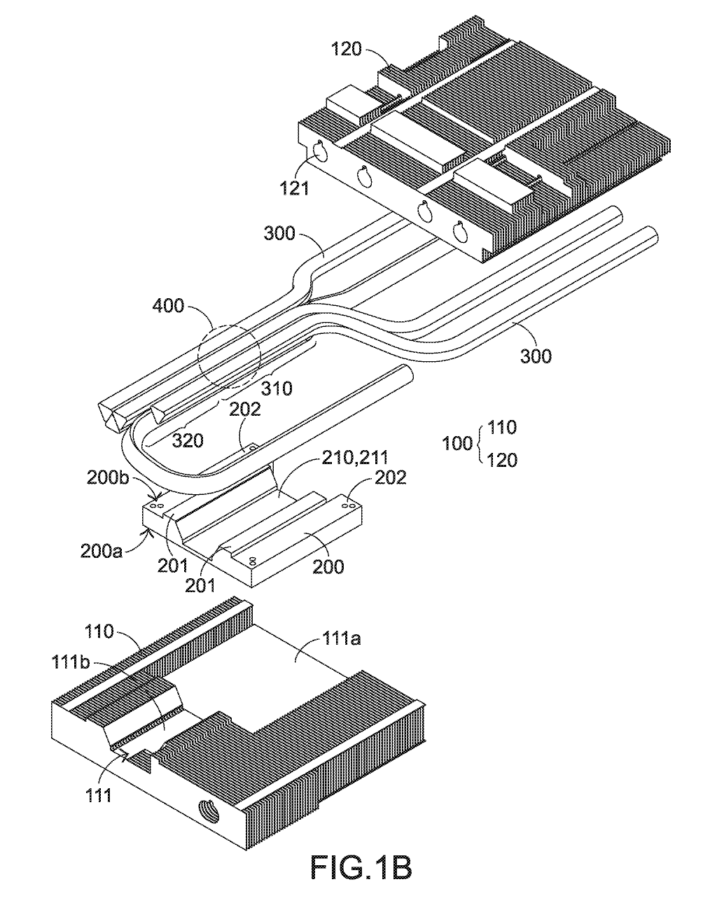

Please refer to FIG. 1A and FIG. 1B. FIG. 1A is a schematic perspective view illustrating the basic concepts of a heat dissipating device according to a first embodiment of the present invention. FIG. 1B is a schematic exploded view illustrating the heat dissipating device of FIG. 1A.

As shown in FIG. 1A and FIG. 1B, the heat dissipating device of this embodiment at least comprises a fin group 100, a heat conduction block 200 and plural heat pipes 300. The fin group 100 comprises a first fin assembly 110 and a second fin assembly 120. The first fin assembly 110 comprises a recess 111. The recess 111 comprises a first concave structure 111a and a second concave structure 111b. The second concave structure 111b is located adjacent to the first concave structure 111a. The heat conduction block 200 comprises a coupling region 210. The coupling region 210 has an accommodation space 211. The plural heat pipes 300 at a first end comprise first-part pipe bodies 310 and second-part pipe bodies 320.

The connecting relationships between the plural heat pipes 300 and the first fin assembly 110, the coupling region 210 of the heat conduction block 200 and the second fin assembly 120 will be described in more details as follows. The heat conduction block 200 is embedded into or locked into the first concave structure 111a of the first fin assembly 110. The accommodation space 211 of the coupling region 210 is in communication with the second concave structure 111b of the recess 111. Moreover, the accommodation space 211 and the second concave structure 111b have the corresponding structures. The second fin assembly 120 further comprises plural openings 121 corresponding to the plural heat pipes 300.

The first-part pipe bodies 310 of the plural heat pipes 300 at the first ends are received within the accommodation space 211 and coupled with the heat conduction block 200. The second-part pipe bodies 320 of the plural heat pipes 300 at the first ends are received within the second concave structure 111b of the recess 111. Consequently, the first ends of the plural heat pipes 300 are coupled with the first fin assembly 110. The second ends of the plural heat pipes 300 are penetrated through and connected with the second fin assembly 120. In other words, after the first ends of the plural heat pipes 300 are coupled with the first fin assembly 110 and the coupling region 210 of the heat conduction block 200, the heat pipes 300 are penetrated through and connected with the second fin assembly 120.

In the above embodiment, the examples of the coupling region 210 and the accommodation space 211 are described, and the second concave structure 111b of the first fin assembly 110 and the accommodation space 211 are in communication with each other and have the similar structures. For example, the accommodation space 211 and the second concave structure 111b are grooves with the identical width and the identical profile. It is noted that the structures of the accommodation space 211 and the second concave structure 111b are not restricted. In the above embodiment, after the heat conduction block 200 is embedded into or locked into the first concave structure 111a, the heat conduction block 200 is coupled with the first concave structure 111a. It is noted that numerous modifications and designs may be made while retaining the teachings of the invention. In other words, the shapes or structures of the above components are presented herein for purpose of illustration and description only. The shapes or structures of the above components may be adjusted according to the applications of the products and the practical requirements.

In the above embodiment, the first-part pipe bodies 310 of all heat pipes 300 are received within the accommodation space 211. Alternatively, in some other embodiment, the first-part pipe bodies 310 of some heat pipes 300 are received within the accommodation space 211. Moreover, depending on the size of the first fin assembly 110, the second concave structure 111b may be selectively omitted. If the second concave structure 111b is omitted, the recess 111 only comprises the first concave structure 111a for receiving the heat conduction block 200 in the first fin assembly 110. That is, the scope of the present invention is not restricted.

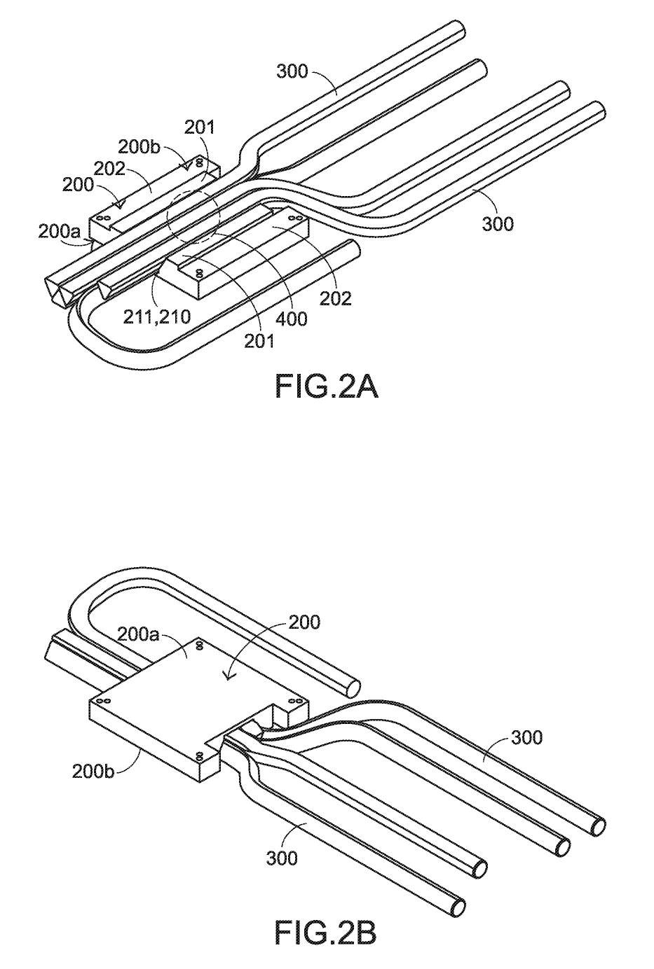

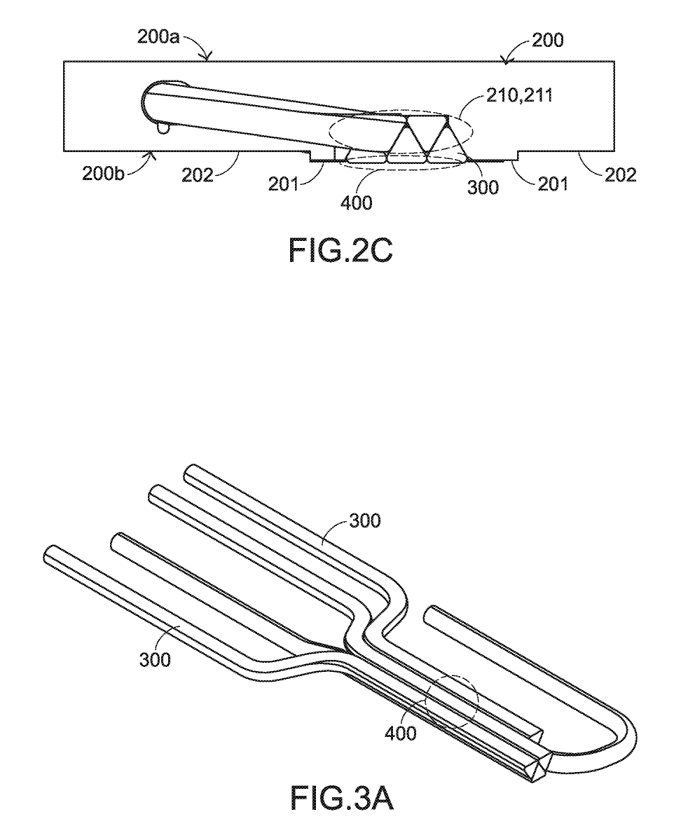

Please refer to FIGS. 2A, 2B and 2C. FIG. 2A is a schematic perspective view illustrating the heat pipes and the heat conduction block of the heat dissipating device of FIG. 1A. FIG. 2B and FIG. 2C are schematic perspective view illustrating heat pipes and the heat conduction block of FIG. 2A and taken along two other viewpoints.

Hereinafter, a method of installing the plural heat pipes 300 and the heat conduction block 200 to define an exposed region 400 will be illustrated as follows. Please refer to FIGS. 2A, 2B and 2C. The heat conduction block 200 comprises a first side 200a and a second side 200b. In this context, the outer edge surfaces 201 and 202 of the heat conduction block 200 are located at the second side 200b. In this embodiment, there is a height difference between the outer edge surface 201 and the outer edge surface 202. Alternatively, in another embodiment, the outer edge surface 201 and the outer edge surface 202 of the heat conduction block 200 are collaboratively formed as a completely flat surface. The exposed region 400 includes the exposed surfaces of the first-part pipe bodies 310 of the heat pipes 300 that are not covered by the outer edge surfaces 201 and 202 of the heat conduction block 200 after the first-part pipe bodies 310 are received within the accommodation space 211 of the coupling region 210.

Particularly, the first side 200a of the heat conduction block 200 is contacted with and fixed in the first concave structure 111a. Consequently, the entire of the heat conduction block 200 is embedded in or locked in the first fin assembly 110. The second side 200b of the heat conduction block 200 has the accommodation space 211 of the coupling region 210 and the exposed region 400. The exposed region 400 is contacted with a heat generation unit (see FIG. 4) in order to remove the heat from the heat generation unit 600. For example, the heat generation unit 600 is a package chip. The operating principles will be described later.

A method of forming the exposed region 400 will be described as follows. In an embodiment, portions of the surfaces of the first-part pipe bodies 310 are coplanar with the outer edge surface 201 in response to an external force. In another embodiment, portions of the surfaces of the first-part pipe bodies 310 are integrally formed and then arranged to be coplanar with the outer edge surface 201. After the corresponding heat pipes 300 are coplanar with the second side 200b of the heat conduction block 200, the exposed region 400 is formed. Since the portions of the surfaces of the first-part pipe bodies 310 are coplanar with the outer edge surface 201, a defined contact plane is contacted with the heat generation unit to smoothly receive and transfer the heat from the heat generation unit. That is, the exposed region 400 is defined by the first-part pipe bodies 310. In this embodiment, the first-part pipe bodies 310 of the plural heat pipes 300 are received in the accommodation space 211, and the exposed region 400 is located beside and coplanar or nearly coplanar with the outer edge surface 201 of the second side 200b of the heat conduction block 200.

In an embodiment, the heat conduction block 200 is a structural body made of a material having a high thermal conductivity (e.g., a metallic material). Preferably, the fins structures 110 and 120 are metallic structural bodies having thermal conductivity higher than the heat conduction block 200. Consequently, the overall heat dissipating efficiency of the heat dissipating device is enhanced.

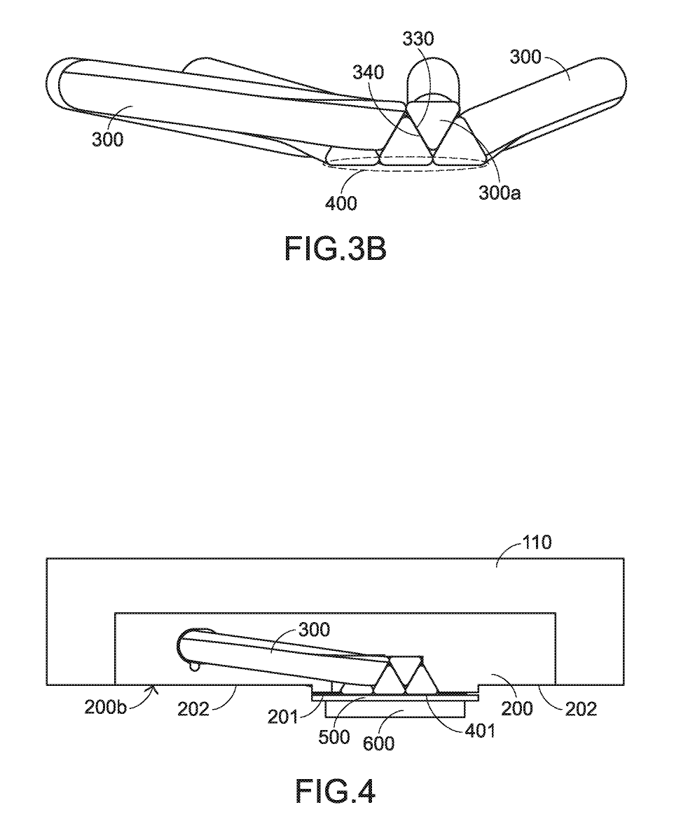

Hereinafter, the structures of the first-part pipe bodies 310 corresponding to the exposed region 400 will be illustrated with reference to FIG. 3A and FIG. 3B. FIG. 3A is a schematic perspective view illustrating the heat pipes of the heat dissipating device of FIG. 1A. FIG. 3B is a schematic perspective view illustrating the heat pipes of FIG. 3A.

In accordance with a feature of the heat dissipating device of the present invention, the first-part pipe bodies 310 of the plural heat pipes 300 have improved profiles. As shown in FIG. 3A and FIG. 3B, the cross section 300a of each first-part pipe body 310 corresponding to the exposed region 400 has a triangular shape. That is, the first-part pipe body 310 corresponding to the exposed region 400 has the structure of a triangular prism. Moreover, the adjacent triangular prisms of the first-part pipe bodies 310 are stacked on each other to define a pipe body assembly with a parallelogram or a trapezoid profile. Moreover, two of the three contact surfaces of each first-part pipe body 310 are contacted with the two contact surfaces of the adjacent first-part pipe bodies 310, or contacted with one contact surface of the adjacent first-part pipe body 310 and the inner surface of the coupling region 210. Since the thermal transfer area between the adjacent first-part pipe bodies 310 is increased, the overall heat dissipating efficiency of the heat dissipating device is enhanced.

In accordance with the feature of the present invention, each first-part pipe body 310 corresponding to the exposed region 400 and received in the accommodation space 211 of the coupling region 210 has a triangular cross section. That is, the first-part pipe bodies 310 received in the accommodation space 211 have the structures of triangular prisms. Moreover, the adjacent triangular prisms of the first-part pipe bodies 310 are stacked on each other to define a pipe body assembly with a parallelogram or a trapezoid profile, and the pipe body assembly is located at the second side 200b of the coupling region 210. Moreover, the first-part pipe bodies 310 of the plural heat pipes 300 are in close contact with each other, and the first-part pipe bodies 310 of the plural heat pipes 300 are completely received within the accommodation space 211 of the coupling region 210.

In the above embodiment, the heat pipes 300 are triangular heat pipes. The prisms with any shape can be used as the heat pipes of the present invention as long as they provide large areas. That is, in accordance with the feature of the present invention, the contact surfaces of every two adjacent heat pipes are flat surfaces that are abutted against or contacted with each other. Consequently, the heat conduction between the adjacent heat pipes can be effectively implemented. In other words, the above example is presented herein for purpose of illustration and description only.

Please refer to FIG. 2C again. The contact surfaces of the interlaced first-part pipe bodies 310 coplanar with the outer edge surface 201 of the second side 200b of the heat conduction block 200 are defined as the exposed region 400. As mentioned above, the first-part pipe bodies 310 are received within the accommodation space 211. Each of the first-part pipe bodies 310 excluding the exposed region 400 comprises a first flat pipe wall 330 and a second flat pipe wall 340 (i.e., the other two contact surfaces of the first-part pipe body 310). The first flat pipe walls 330 and the second flat pipe walls 340 of the adjacent the first-part pipe bodies 310 are abutted against each other and contacted with each other. Consequently, the heat can be directly transferred through the adjacent heat pipes 300 through thermal conduction.

FIG. 4 is a schematic front view illustrating the basic concepts of a heat dissipating device according to a second embodiment of the present invention.

As shown in FIG. 4, the heat dissipating device of this embodiment further comprises a temperature homogenizing plate 500. The adjacent triangular prisms of the first-part pipe bodies 310 of the heat pipes 300 corresponding to the exposed region 400 are stacked on each other to define a pipe body assembly with a trapezoid profile. The pipe body assembly with the trapezoid profile and the outer edge surface 201 of the second side 200b of the heat conduction block 200 are collaboratively defined as the exposed region 400. The exposed region 400 is contacted with the heat generation unit 600 in order to remove the heat from the heat generation unit 600. The temperature homogenizing plate 500 is in close contact with the exposed region 400, and arranged between the exposed region 400 and the heat generation unit 600. The other contact surfaces corresponding to the exposed region 400 are embedded in or locked in the first fin assembly 110. As shown in FIG. 1A, the fin numbers of the fin assemblies 110 and 120 of the fin group 100 may be adjusted according to the practical requirements of the overall heat dissipating device. It is noted that numerous modifications and alterations may be made while retaining the teachings of the invention and the detailed descriptions thereof are omitted.

Moreover, the portions of the heat pipes 300 outside the exposed region 400 (i.e., the portions of the heat pipes 300 excluding the first-part pipe bodies 310) can be connected with the fin assemblies 110 and 120 of the fin group 100 through any connecting means. That is, the connecting means are not restricted to the recess 111 and the openings 121. In another embodiment, the portions of the heat pipes 300 excluding the first-part pipe bodies 310 are completely embedded in or locked in a single fin group 100 or plural fin groups 100. However, the portions of the heat pipes corresponding to the exposed region 400 are triangular pipe bodies that are stacked on each other to be contacted with the heat generation unit 600. Moreover, the area of the exposed region 400 of the plural heat pipes 300 may be adjusted according to the contact area of the heat generation unit 600.

Moreover, the triangular heat pipes 300 can be fabricated by various methods. In accordance with a fabricating method, portions or the entire of the pipe bodies are integrally formed as the triangular heat pipes. In accordance with another fabricating method, molded circular heat pipes are flattened or pressed to nearly-triangular heat pipes by a stamping process or a roll pressing process. It is noted that the methods of fabricating the heat pipes are not restricted to the above methods.

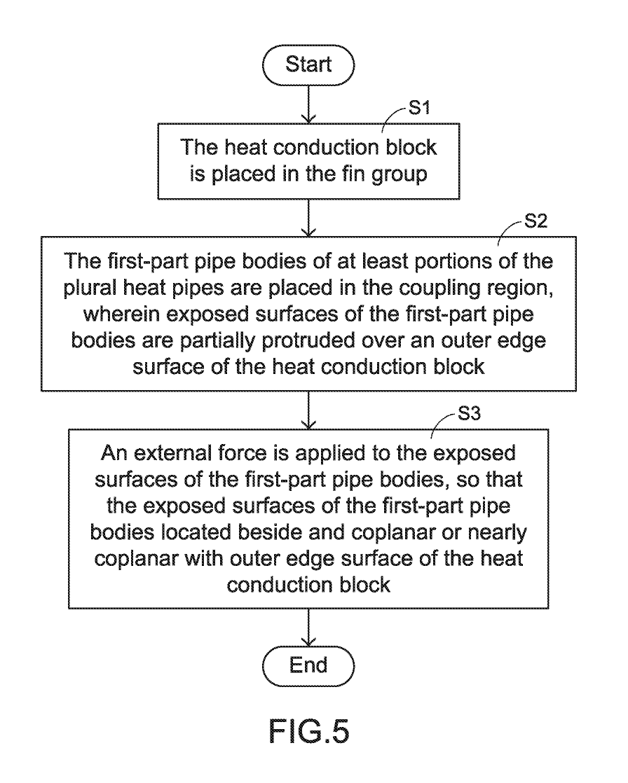

A method of fabricating the first-part pipe bodies of the heat pipes will be described as follows. FIG. 5 is a flowchart illustrating a method for increasing heat conduction of a heat dissipating device according to an embodiment of the present invention.

Please refer to FIG. 1B and FIG. 5. The heat dissipating device of this embodiment is used for increasing the contact area between the adjacent heat pipes 300 within the accommodation space 211 so as to increase the heat transfer area and the heat dissipating efficiency of the heat pipes 300. In this embodiment, heat dissipating device at least comprises a fin group 100 with two fin assemblies 110, 120, a heat conduction block 200 with a coupling region 210, and plural heat pipes 300. The method comprises the following steps.

In a step S1, the heat conduction block 200 is placed in the first fin assembly 110.

In a step S2, the first-part pipe bodies 310 of at least portions of the plural heat pipes 300 are placed in the accommodation space 211 of the coupling region 210, wherein exposed surfaces of the first-part pipe bodies 310 are partially protruded over an outer edge surface 201 of the heat conduction block 200.

In a step S3, an external force is applied to the exposed surfaces of the first-part pipe bodies 310, so that the exposed surfaces of the first-part pipe bodies 310 are located beside and coplanar or nearly coplanar with the outer edge surface 201 of the heat conduction block 200.

Firstly, the first-part pipe bodies 310 of the plural heat pipes 300 are placed in the accommodation space 211. The heat pipes 300 are flat pipes or circular pipes. The exposed surfaces of the first-part pipe bodies 310 in the accommodation space 211 are partially protruded over the outer edge surface 201 of the heat conduction block 200. Then, by a stamping process or a roll pressing process, an external force to the exposed surfaces of the first-part pipe bodies 310 that are protruded over the outer edge surface 201 of the heat conduction block 200. Consequently, the exposed surfaces of the first-part pipe bodies 310 are coplanar or nearly coplanar with the outer edge surface 201 of the heat conduction block 200. Meanwhile, the exposed region 400 is defined. The exposed region 400 is contacted with the temperature homogenizing plate 500 or the heat generation unit 600 to transfer heat. After the external force is applied to the exposed surfaces of the first-part pipe bodies 310, the first-part pipe bodies 310 have nearly-polygonal profiles. The polygonal pipe body is composed of plural flat walls. Consequently, the polygonal pipe body has a polygonal cross section. Due to the plural flat walls, the adjacent first-part pipe bodies 310 are in surface contact. Consequently, the contact area between the first-part pipe bodies 310 is increased, and the heat conduction efficiency of transferring heat is enhanced.

Moreover, the polygonal pipe body is a regular pipe body or an irregular pipe body. In the above embodiment, the triangular pipe bodies and the nearly-triangular pipe bodies are the examples of the polygonal pipe bodies. The triangular pipe bodies are the examples of regular pipe body. In some other embodiments, the polygonal pipe bodies are triangular pipe bodies, nearly-triangular pipe bodies or any other irregular pipe bodies. The above examples are presented herein for purpose of illustration and description only. In accordance with the feature of the present invention, the heat transfer area between the first-part pipe bodies 310 within the accommodation space 211 is increased, and the heat conduction efficiency of the first-part pipe bodies 310 is enhanced.

From the above descriptions, portions or the entire of the pipe bodies are integrally formed as the triangular heat pipes or other flat surface structures to be contacted with other heat pipes, or the circular heat pipes or the flat heat pipes are machined to form the triangular heat pipes or other flat surface structures to be contacted with other heat pipes. By using these heat pipes, the circulation of the working liquid for heat transfer is not hindered. Moreover, since the contact area between the adjacent heat pipes is increased, the overall heat dissipating efficiency of the heat dissipating device is largely enhanced. Moreover, the present invention provides the designs of the heat conduction block and the coupling region. Since the heat conduction block is closely combined with the heat pipes and the fin group, the contact areas between the heat conduction block, the fin group and the heat pipes are increased and the purposes of fixing the heat pipes and increasing the heat dissipating efficiency are achieved.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A heat dissipating device, at least comprising:
a fin group;
a heat conduction block having a coupling region, wherein the heat conduction block is installed in the fin group, and the coupling region has an accommodation space; and
plural heat pipes, wherein first ends of at least portions of the plural heat pipes comprise first-part pipe bodies, wherein the first-part pipe bodies are included in the coupling region, and the first-part pipe bodies are received within the accommodation space,
wherein an exposed region of the first-part pipe bodies is located beside and coplanar or nearly coplanar with an outer edge surface of the heat conduction block in response to an external force, and every two adjacent ones of the first-part pipe bodies are in surface contact with each other through respective flat pipe walls, so that the first-part pipe bodies are abutted against each other to transfer heat directly.

2. The heat dissipating device according to claim 1, wherein every two adjacent ones of the first-part pipe bodies at least comprise a first flat pipe wall and a second flat pipe wall, respectively, wherein the first flat pipe wall and the second flat pipe wall are in surface contact with each other and abutted against each other to transfer heat directly.

3. The heat dissipating device according to claim 1, wherein the fin group at least comprises a first fin assembly with a recess, and the heat conduction block is received in the recess.

4. The heat dissipating device according to claim 1, wherein each of the first-part pipe bodies is a polygonal pipe body with plural flat pipe walls, wherein the polygonal pipe body is a regular pipe body or an irregular pipe body.

5. The heat dissipating device according to claim 4, wherein the regular pipe body is one of a triangular pipe body and a nearly-triangular pipe body, or the regular pipe body is one of a rectangular pipe body and a nearly-rectangular pipe body.

6. The heat dissipating device according to claim 3, wherein the fin group further comprises a second fin assembly, wherein the second fin assembly is located beside and extended to second ends of the at least portions of the plural heat pipes, and the at least portions of the plural heat pipes are penetrated through the second fin assembly.

7. The heat dissipating device according to claim 6, wherein a thermal conductivity coefficient of the first fin assembly and a thermal conductivity coefficient of the second fin assembly are both higher than a thermal conductivity coefficient of the heat conduction block.

8. The heat dissipating device according to claim 1, wherein the exposed region of the first-part pipe bodies is contacted with a heat generation unit, and the heat from the heat generation unit is conducted by the first-part pipe bodies.

9. The heat dissipating device according to claim 8, wherein the heat dissipating device further comprises a temperature homogenizing plate, and the uniform temperature plate is arranged between the heat generation unit and the first-part pipe bodies.

10. A method for increasing heat conduction of a heat dissipating device, the heat dissipating device at least comprising a fin group, a heat conduction block with a coupling region and plural heat pipes, the method comprising steps of:
(A) placing the heat conduction block in the fin group;
(B) placing first-part pipe bodies of at portions of the plural heat pipes in the coupling region, wherein the first-part pipe bodies are located at first ends of the at portions of the plural heat pipes, and exposed surfaces of the first-part pipe bodies are partially protruded over an outer edge surface of the heat conduction block; and
(C) applying an external force to the exposed surfaces of the first-part pipe bodies, so that the exposed surfaces of the first-part pipe bodies are located beside and coplanar or nearly coplanar with the outer edge surface of the heat conduction block.

11. The method according to claim 10, wherein the coupling region has an accommodation space, and the first-part pipe bodies of the at least portions of the plural heat pipes are received within the accommodation space.

12. The method according to claim 11, wherein every two adjacent ones of the first-part pipe bodies at least comprise a first flat pipe wall and a second flat pipe wall, respectively, wherein the first flat pipe wall and the second flat pipe wall are in surface contact with each other and abutted against each other to transfer heat directly.

13. The method according to claim 11, wherein the fin group at least comprises a first fin assembly with a recess, and the heat conduction block is received in the recess.

14. The method according to claim 11, wherein each of the first-part pipe bodies is a polygonal pipe body with plural flat pipe walls.

15. The method according to claim 14, wherein the polygonal pipe body is a regular pipe body or an irregular pipe body.

16. The method according to claim 15, wherein the regular pipe body is one of a triangular pipe body and a nearly-triangular pipe body, or the regular pipe body is one of a rectangular pipe body and a nearly-rectangular pipe body.

17. The method according to claim 13, wherein the fin group further comprises a second fin assembly, wherein the second fin assembly is located beside and extended to second ends of the at least portions of the plural heat pipes, and the at least portions of the plural heat pipes are penetrated through the second fin assembly.

18. The method according to claim 17, wherein a thermal conductivity coefficient of the first fin assembly and a thermal conductivity coefficient of the second fin assembly are both higher than a thermal conductivity coefficient of the heat conduction block.

19. The method according to claim 10, wherein the exposed surfaces of the first-part pipe bodies are contacted with a heat generation unit, and the heat from the heat generation unit is conducted by the first-part pipe bodies.

20. The method according to claim 19, wherein the heat dissipating device further comprises a temperature homogenizing plate, and the uniform temperature plate is arranged between the heat generation unit and the first-part pipe bodies.
